(19) United States
(12) Patent Application Publication
(10) Pub. No.: US 2012/0267761 A1
(43) Pub. Date: Oct. 25, 2012

(54) CAPACITOR

(75) Inventors: Chang Sun Kim, Seoul (KR); Seong Hoon Choi, Seoul (KR); Jang Hyun Park, Seoul (KR); Seung-Tak Ryu, Daejeon (KR); Ba-Ro-Saim Sung, Daejeon (KR); Dong-Shin Jo, Daejeon (KR)

(73) Assignees: Korea Advanced Institute of Science and Technology, Daejeon (KR); Electronics and Telecommunications Research Institute, Daejeon (KR)

(21) Appl. No.: 13/426,328

(22) Filed: Mar. 21, 2012

(30) Foreign Application Priority Data
Apr. 21, 2011 (KR) 10-2011-0037097

(51) Int. Cl. H01L 29/92

(52) U.S. Cl. 257/532; 257/E29.342

(57) ABSTRACT

A capacitor is provided. The capacitor includes first and second electrode layers facing each other, a first conductive pattern disposed between the first and second electrode layers, the first conductive pattern forming a closed loop in plan view, a second conductive pattern disposed within an inner space surrounded by the closed loop of the first conductive pattern, the second conductive pattern being spaced from the first conductive pattern, and a first contact plug passing through the second conductive pattern to contact the first and second electrode layers.

### CROSS-REFERENCE TO RELATED APPLICATIONS

This U.S. non-provisional patent application claims priority under 35 U.S.C. §119 of Korean Patent Application No. 10-2011-0037097, filed on Apr. 21, 2011, the entire contents of which are hereby incorporated by reference.

### BACKGROUND OF THE INVENTION

The present invention disclosed herein relates to a capacitor.

Electronic devices included in various electronic equipment such as analog to digital convertors (ADCs) and digital to analog convertors (DACs) are important components that determine the quality of the electronic equipments. As electronic equipment is being made with large-capacitance, multi-functional, and miniaturized, there is increasing demand for electronic equipment having improved reliability and more favorable properties.

Capacitors having large-capacitance and high reliability are required to satisfy these demands, and research on laminated capacitors in which electrodes are laminated to increase effective area for generating capacitance is therefore underway.

### SUMMARY OF THE INVENTION

The present invention provides a capacitor having high reliability.

The present invention also provides a capacitor having an increased effective area for generating capacitance.

Embodiments of the present invention provide capacitors including: first and second electrode layers facing each other; a first conductive pattern disposed between the first and second electrode layers, the first conductive pattern forming a closed loop in plan view; a second conductive pattern disposed within an inner space surrounded by the closed loop of the first conductive pattern, the second conductive pattern being spaced from the first conductive pattern; and a first contact plug passing through the second conductive pattern to contact the first and second electrode layers.

In some embodiments, the first conductive pattern may includes first extension portions extending in a first direction parallel to a top surface of the first electrode layer and second extension portions extending in a second direction parallel to the top surface of the first electrode layer and crossing the first direction, and the first and second extension portions may form a plurality of closed loops in plan view.

In other embodiments, the plurality of closed loops may define a plurality of inner spaces surrounded by the plurality of closed loops, respectively, the second conductive pattern may be provided in plurality, and the plurality of second conductive patterns may be disposed within the plurality of inner spaces, respectively.

In still other embodiments, the plurality of second conductive patterns may extend in the first direction within the inner spaces.

In even other embodiments, the first extension portions and the second conductive patterns may be alternately disposed in the second direction.

In yet other embodiments, the plurality of second conductive patterns may have the same length in the first direction.

In further embodiments, one first extension portion of the first extension portions may have a length greater than those of the other first extension portions.

In still further embodiments, the second extension portions may be provided in a pair, and one second extension portion of the pair of second extension portions may connect one ends of the first extension portions to each other, and the other extension portion of the pair of second extension portions may connect the other ends of the first extension portions to each other.

In even further embodiments, the capacitors may further include a third conductive pattern between the first and second electrode layers, wherein the third conductive pattern may surround the outside of the first conductive pattern and be spaced from the first conductive pattern.

In yet further embodiments, a capacitance per unit area between the first and second conductive patterns may be equal to a capacitance per unit area between the first and third conductive patterns.

In much further embodiments, the first to third conductive patterns may be disposed at the same level with respect to the top surface of the first electrode layer.

In still much further embodiments, the capacitors may further include: a first dielectric disposed between the first to third conductive patterns and the first electrode layer; and a second dielectric disposed between the first to third conductive patterns and the second electrode layer, the second dielectric filling spaces between the first to third conductive patterns, wherein the first contact plug may further pass through the first and second dielectrics.

In even much further embodiments, the capacitor may further include a second contact plug passing through the second dielectric, the third conductive pattern, and the first dielectric to contact the first and second electrode layers.

In yet much further embodiments, the first to third conductive patterns may be manufactured through the same process.

In even still much further embodiments, the first conductive pattern may include a first extension portion extending in the first direction parallel to the top surface of the first electrode layer and a second extension portion extending the second direction perpendicular to the first direction, the second conductive pattern may extend in the first direction, and a distance between the first extension portion and the second conductive pattern in the second direction may be equal to a distance between the second extension portion and the second conductive pattern in the first direction.

In yet still much further embodiments, the third conductive pattern may include a first portion extending in the first direction and a second portion extending in the second direction, and a distance between the first extension portion and the first portion in the second direction may be equal to a distance between the second extension portion and the second portion in the first direction.

In yet even much further embodiments, the distance between the first extension portion and the second conductive pattern in the second direction may be equal to a distance between the first extension portion and the first portion in the second direction.

In yet even still much further embodiments, a distance between the first conductive pattern and the first electrode layer in a direction perpendicular to the top surface of the first electrode layer may be equal to a distance between the first conductive pattern and the second electrode layer.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a perspective view of a capacitor according to an embodiment of the present invention;

FIGS. 2A and 2B are sectional views of the capacitor according to the embodiment of the present invention and respectively illustrate sectional views taken along line I-I′ and II-II′ of FIG. 1;

FIGS. 3A, 3B, 4A, and 4B are sectional views illustrating a process of manufacturing a capacitor according to an embodiment of the present invention; and

FIGS. 5A, 5B, 6A, and 6B are sectional views illustrating a process of manufacturing a capacitor according to another embodiment of the present invention.

### DETAILED DESCRIPTION OF PREFERRED EMBODIMENTS

The objects, other objectives, features, and advantages of the present invention will be understood without difficulties through preferred embodiments below related to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

In the specification, it will be understood that when a film (or layer) is referred to as being ‘on’ another film (or layer) or substrate, it can be directly on the other film (or layer) or substrate, or intervening layers may also be present. Also, in the figures, the sizes and thicknesses of components are exaggerated for clarity of illustration. Also, though terms like a first, a second, and a third are used to describe various regions and films (or layers) in various embodiments of the present invention, the regions and the films are not limited to these terms. These terms are used only to discriminate one region or film (or layer) from another region or film (or layer). Therefore, a layer referred to as a first layer in one embodiment can be referred to as a second layer in another embodiment. An embodiment described and exemplified herein includes a complementary embodiment thereof.

In the specification, ‘and/or’ means that it includes at least one of listed components. In the specification, like reference numerals refer to like elements throughout.

A capacitor according to an embodiment of the present invention will be described below.

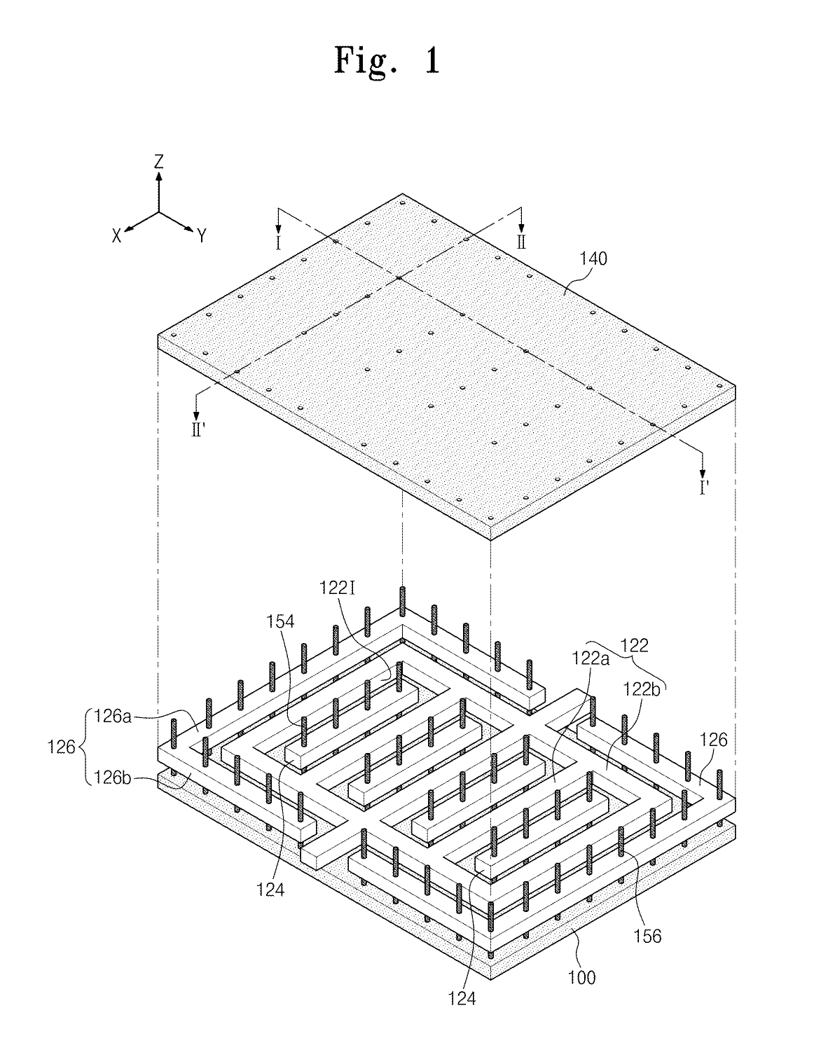

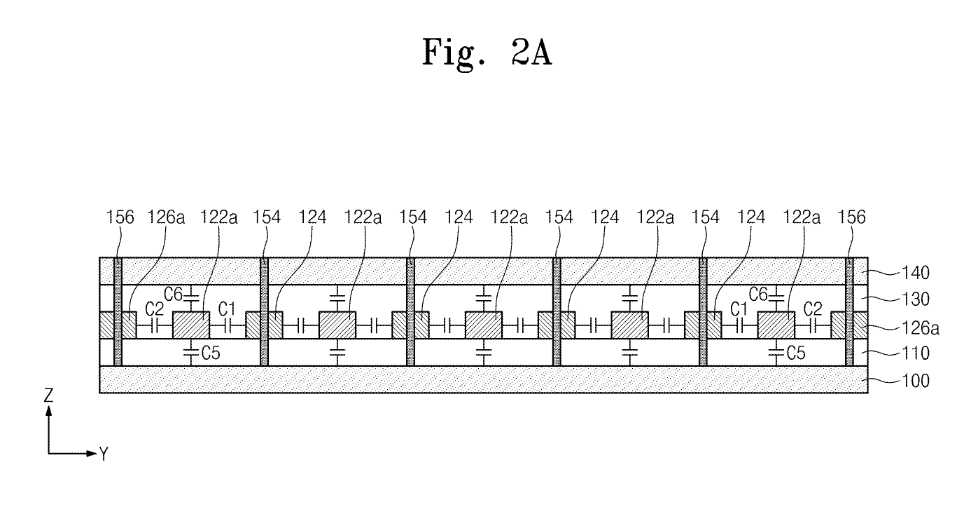

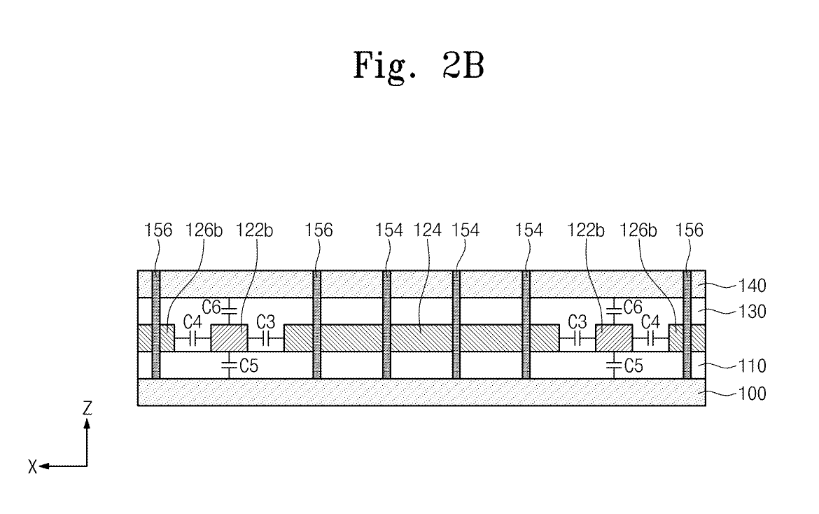

FIG. 1 is a perspective view of a capacitor according to an embodiment of the present invention. FIGS. 2A and 2B are sectional views of the capacitor according to the embodiment of the present invention and respectively illustrate sectional views taken along line I-I′ and II-II′ of FIG. 1. For convenience of recognition, in FIG. 1, figures of first and second dielectrics 110 and 130 and first to third conductive patterns 122, 124, and 126, which will be described later, will be omitted.

Referring to FIGS. 2A and 2B, a capacitor according to an embodiment of the present invention may include a first electrode layer 100, a first conductive pattern 122, a second conductive pattern 124, a third conductive pattern 126, a second electrode layer 140, and a plurality of contact plugs 154 and 156.

The first electrode layer 100 and the second electrode layer 140 may face each other. Each of the first electrode layer 100 and the second electrode layer 140 may have a flat plate shape. According to an embodiment, the first and second electrode layers 100 and 140 may be formed of the same metal.

The first to third conductive patterns 122, 124, and 126 may be disposed between the first electrode layer 100 and the second electrode layer 140. The first to third conductive patterns 122, 124, and 126 may be spaced from each other. The first to third conductive patterns 122, 124, and 126 may be disposed on the same level as each other relative to a top surface of the first electrode layer 100. The first to third conductive patterns 122, 124, and 126 may have the same thickness. The first to third conductive patterns 122, 124, and 126 may be manufactured through the same process. The first to third conductive patterns 122, 124, and 126 may be formed of the same material.

A first dielectric 110 may be disposed between the first to third conductive patterns 122, 124, and 126 and the first electrode layer 100. A second dielectric 130 may be disposed between the first to third conductive patterns 122, 124, and 126 and the second electrode layer 140. The first and second dielectrics 110 and 130 may be formed of the same material.

The first conductive pattern 122 may include a plurality of first extension portions 122a and a plurality of second extension portions 122b. The first extension portions 122a may extend in a first direction. The second extension portions 122b may extend in a second direction crossing the first direction. The second direction may be perpendicular to the first direction. The first and second directions may be parallel to the top surface of the first electrode layer 100. In drawings, the first direction may denote an X-axis direction, and the second direction may denote a Y-axis direction.

The second extension portions 122b may be provided in pair. In the pair of second extension portions 122b, one extension portion may connect one ends of the first extension portions 122a adjacent to each other to each other, and the other extension portion may connect the other ends of the first extension portions 122a adjacent to each other to each other.

The pair of second extension portions 122b may have the same length. Each of the first extension portions 122a in the first direction may have a length less than that of each of the second extension portions 122b in the second direction. In the first extension portions 122a, one extension portion in the first direction may have a length greater than that of each of other extension portions 122a in the first direction. The other first extension portions 122a in the first direction may have the same length.

In plan view, the first and second extension portions 122a and 122b crossing each other may form a plurality of closed loops. For example, the first extension portions 122a and the pair of second extension portions 122b which are adjacent to each other may provide the plurality of closed loops. Unlike those shown in the drawings, each of the first extension portions 122a and the second extension portions 122b may be provided in pair so that the first conductive pattern 122 forms one closed loop.

In plan view, inner spaces 1221 respectively surrounded by the plurality of closed loops of the first conductive pattern 122 may be defined. The inner spaces 1221 may extend in the first direction. In plan view, the inner spaces 1221 may have the same area and/or shape. According to an embodiment, in plan view, each of the inner spaces 1221 may have a square shape.

The plurality of second conductive patterns 124 may be disposed within the plurality of inner spaces 1221, respectively. For example, the pair of first extension portions 122a and the pair of second extension portions 122b which are adjacent to each other form one closed loop, and one second conductive pattern 124 may be disposed within one closed loop. The second conductive pattern and the first extension portions 122a which are adjacent to each other may have the same distance therebetween. The second conductive pattern 124 and the second extension portions 122b may have the same distance therebetween.

The second conductive patterns 124 my have line shapes extending parallel to each other in the first direction. The second conductive patterns 124 may have the same length in the first direction. The first extension portions 122a and the second conductive patterns 124 may be alternately arranged in the second direction.

The first contact plugs 154 may pass through the second conductive patterns 124 and the first and second dielectrics 110 and 130. The first contact plugs 154 may further pass through the second electrode layer 140. Unlike those shown in the drawings, the first contact plugs 154 may further pass through the first electrode layer 100. According to an embodiment, the plurality of first contact plugs 154 may pass through one second conductive pattern 124. The plurality of first contact plugs 154 passing through one second conductive pattern 124 may be arranged in the first direction. Unlike those shown in the drawings, one first contact plug 154 may pass through one second conductive pattern 124.

The first contact plugs 154 may pass through the second conductive patterns 124 and the first and second dielectrics 110 and 130 to contact the first electrode layer 100, the second electrode layer 140, and the second conductive patterns 124. Thus, the second conductive patterns 124, the first electrode layer 100, and the second electrode layer 140 may be electrically connected to each other.

The third conductive pattern 126 may be disposed outside the first conductive pattern 122. The third conductive pattern 126 may be provided in pair. The pair of third conductive patterns 126 may be spaced from each other. In plan view, the pair of third conductive patterns may surround the first conductive pattern 122. Each of the third conductive patterns 126 may include a first portion 126a extending in the first direction and a pair of second portions 126b extending in the second direction. In each of the third conductive patterns 126, the pair of second conductive portions 126b may be connected to both ends of the first portion 126a, respectively.

The first portions 126a of the third conducive patterns 126 may be disposed outside the first extension portions 122a connected to both ends of the second extension portions 122b, respectively. The second portions 126b of the third conductive patterns 126 may be disposed outside the second extension portions 122b, respectively.

One first extension portion 122a having a length greater than those of the other first extension portions 122a of the first extension portions 122a in the first direction may extend between the pair of third conductive patterns 126 in the first direction. For example, the second portions 126b may have one ends and the other ends connected to the first portions 126a. One first extension portion 122a may extend between the one ends of the second portions 126b adjacent to each other.

The second contact plugs 156 may pass through the third conductive patterns 126 and the first and second dielectrics 110 and 130. The second contact plugs 156 may further pass through the second electrode layer 140. Unlike those shown in the drawings, the second contact plugs 156 may further pass through the first electrode layer 100. According to an embodiment, the plurality of second contact plugs 156 may pass through one third conductive pattern 126. According to an embodiment, the plurality of second contact plugs 156 pass through one first portion 126a, and also, the plurality of second contact plugs 156 may pass through one second portion 126b. The plurality of second contact plugs 156 passing through one first portion 126a may be arranged in the first direction, and the plurality of second contact plugs 156 passing through one second portion 126b may be arranged in the second direction. Unlike those shown in the drawings, one second contact plug 156 may pass through one third conductive pattern 126.

The second contact plugs 156 may pass through the third conductive patterns 126 and the first and second dielectrics 110 and 130 to contact the first electrode layer 100, the second electrode layer 140, and the third conductive patterns 126. Thus, the second conductive patterns 124, the first electrode layer 100, and the second electrode layer 130 may be electrically connected to each other.

The first and second dielectrics 110 and 130 may be disposed between the first conductive pattern 122 and the first electrode layer 100 and between the first conductive pattern 122 and the second electrode layer 140, respectively. The second dielectric 130 may be disposed between the first conductive pattern 122 and the second conductive patterns 124 and between the first conductive pattern 122 and the third conductive patterns 126. Thus, the first conductive pattern 122 may be electrically insulated from the first electrode layer 100, the second electrode layer 140, the second conductive pattern 24, and the third conductive patterns 126.

The first electrode layer 100, the second electrode layer 140, the second conductive patterns 124, and the third conductive patterns 126 may be electrically connected to each other by the first and second contact plugs 154 and 156.

The first extension portions 122a and the second conductive patterns 124 which are adjacent to each other may be spaced a first distance from each other in the second direction. Sidewalls of the second conductive patterns 124 facing the first extension portions 122a may have the same area. The same first capacitance C1 may be defined between the first extension portions 122a and the second conductive patterns 124 which are adjacent to each other.

The first extension portions 122a and the first portions 126a which are adjacent to each other may be spaced a second distance from each other in the second direction. Sidewalls of the first portions 126a facing the first extension portions 122a may have the same area. The same second capacitance C2 may be defined between the first extension portions 122a and the first portions 126a which are adjacent to each other.

The first distance may be equal to the second distance. In this case, the first capacitance C1 per unit area may be equal to the second capacitance C2 per unit area.

The second extension portions 122b and the second conductive patterns 124 which are adjacent to each other may be spaced a third distance from each other in the first direction. Sidewalls of the second conductive patterns 124 facing the second extension portions 122b may have the same area. The same third capacitance C3 may be defined between the second extension portions 122b and the second conductive patterns 124 which are adjacent to each other.

The third distance may be equal to each of the first and second distances. In this case, the third capacitance C3 per unit area may be equal to each of the first and second capacitances C1 and C2 per unit area.

The second extension portions 122b and the second portions 126b which are adjacent to each other may be spaced a fourth distance from each other in the first direction. Sidewalls of the second portions 126b facing the second extension portions 122b may have the same area. The same fourth capacitance C4 may be defined between the second extension portions 122b and the second portions 126b which are adjacent to each other.

The fourth distance may be equal to each of the first to third distances. In this case, the fourth capacitance C4 per unit area may be equal to each of the first to third capacitances C1, C2 and C3 per unit area.

The first conductive pattern 122 and the first electrode layer 100 may be spaced a fifth distance from each other in a third direction. The first conductive pattern 122 and the second electrode layer 140 may be spaced a sixth distance from each other in the third direction. The third direction may be perpendicular to each of the first and second directions. In the drawings, the third direction may be a Z-axis direction.

The fifth distance may be equal to the sixth distance, and the first and second dielectrics 110 and 130 may be formed of the same material. In this case, a fifth capacitance C5 defined between the first conductive pattern and the first electrode layer 100 may be equal to a sixth capacitance C6 defined between the first conductive pattern 122 and the second electrode layer 140.

According to an embodiment of the present invention, the second conductive patterns 124 may be disposed within the closed loops of the first conductive pattern 122, the third conductive patterns 126 may surround the first conductive pattern 122, and the first conductive pattern 122 may be disposed between the first and second electrode layers 100 and 140. Thus, the first conductive pattern 122 may be shielded from the outside to increase an effective overlapping area between the first conductive pattern 122 and the other components 100, 124, 126, and 140 in which capacitances are defined therebetween.

A method of manufacturing a capacitor according to an embodiment of the present invention will be described below.

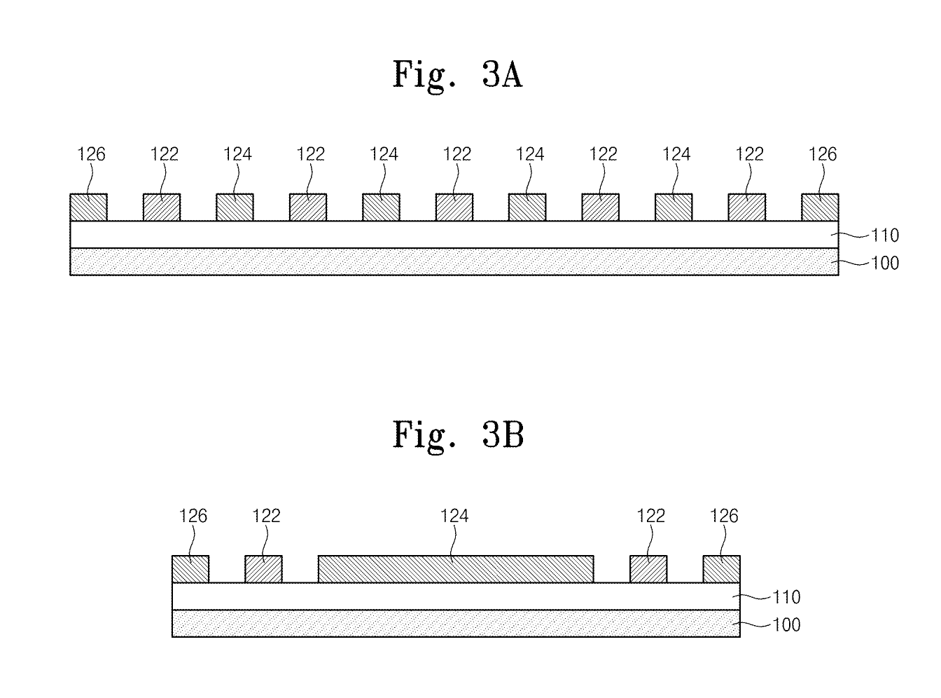

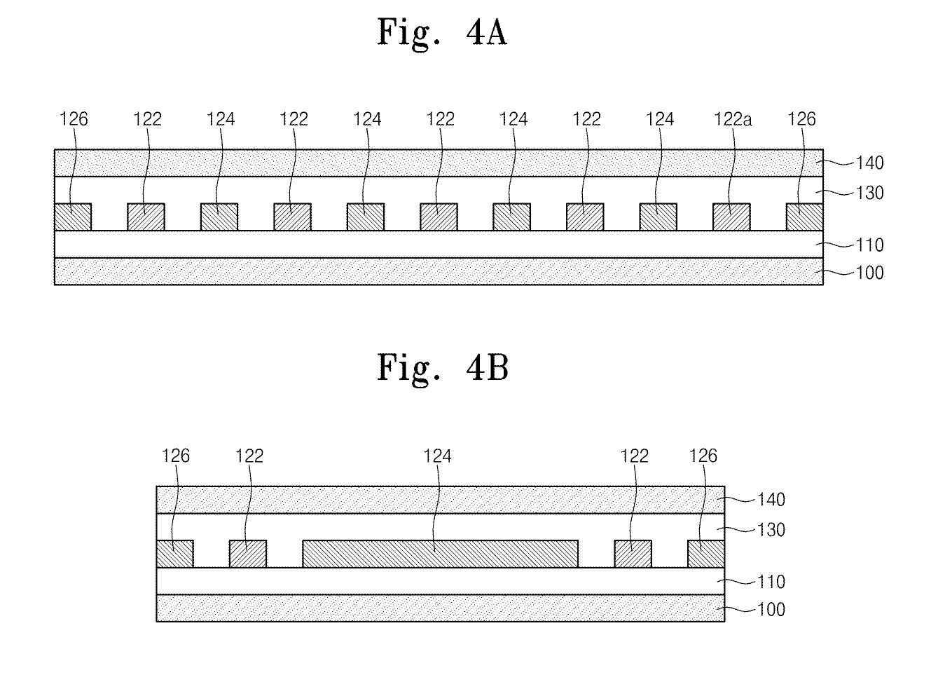

FIGS. 3A, 3B, 4A, and 4B are sectional views illustrating a process of manufacturing a capacitor according to an embodiment of the present invention. FIGS. 3A and 4A are sectional views taken along the line I-I′ of FIG. 1. FIGS. 3B and 4B are sectional views taken along the line II-II′ of FIG. 1.

Referring to FIGS. 3A and 3B, a first electrode layer 100 is prepared. The first electrode layer 100 may be a metal layer. For example, the metal layer may be formed of one of copper, aluminum, and an alloy thereof.

A first dielectric 110 may be formed on the first electrode layer 100. The first dielectric 110 may be an oxide layer. For example, the oxide layer may be a silicon oxide layer.

First to third conductive patterns 122, 124, and 126 which are described with reference to FIG. 1 may be formed on the first dielectric 110. The first to third conductive patterns 122, 124, and 126 may be formed through the same process. For example, a conductive layer may be formed on the first dielectric 110, and then the conductive layer may be patterned to form the first to third conductive patterns 122, 124, and 126. The conductive layer may be formed of one of copper, aluminum, and an alloy thereof. The conductive layer may be patterned using a photolithography process.

Referring to FIGS. 4A and 4B, after the first to third conductive patterns 122, 124, and 126 are formed, a second dielectric 130 covering the first to third conductive patterns 122, 124, and 126 may be formed on the first dielectric 110. The second dielectric 130 may fill spaces between the first conductive pattern 122 and the second conductive patterns 124 and between the first conductive pattern 122 and the third conductive patterns 126. The second dielectric 130 and the first dielectric 110 may be formed of the same material. A planarization process may be performed on the second dielectric 130 to planarize a top surface of the second dielectric 130. The planarization process may be an etch back process or a chemical mechanical polishing (CMP) process.

A second electrode layer 140 may be formed on the second dielectric 130. The second electrode layer 140 may be a metal layer. For example, the second electrode layer 140 may be formed of the same material as that of the first electrode layer 100.

Referring to FIGS. 1, 2A, and 2B, after the second electrode layer 140 is formed, first contact plugs 154 and second contact plugs 156 may be formed. The first contact plugs 154 may pass through the second electrode layer 140, the second dielectric 130, the second conductive patterns 124, and the first dielectric 110 to contact the first electrode layer 100. The second contact plugs 156 may pass through the second electrode layer 140, the second dielectric 130, the third conductive patterns 126, and the first dielectric 110 to contact the first electrode layer 100. Unlike those shown in the drawings, the first and second contact plugs 154 and 156 may further pass through the first electrode layer 100.

The second conductive patterns 124 may be electrically connected to the first and second electrode layers 100 and 140 by the first contact plugs 154. The third conductive patterns 126 may be electrically connected to the first and second electrode layers 100 and 140 by the second contact plugs 156.

The first and second contact plugs 154 and 156 may pass through the second electrode layer 140, the second dielectric 130, the second conductive patterns 124, and the first dielectric 110 to form first contact holes exposing the first electrode layer 100 and pass through the second electrode layer 140, the second dielectric 130, the third conductive patterns 123, and the first dielectric 110 to form second contact holes exposing the first electrode layer 100. The contact holes may be filled with a conductive material.

A method of manufacturing a capacitor according to another embodiment of the present invention will be described below.

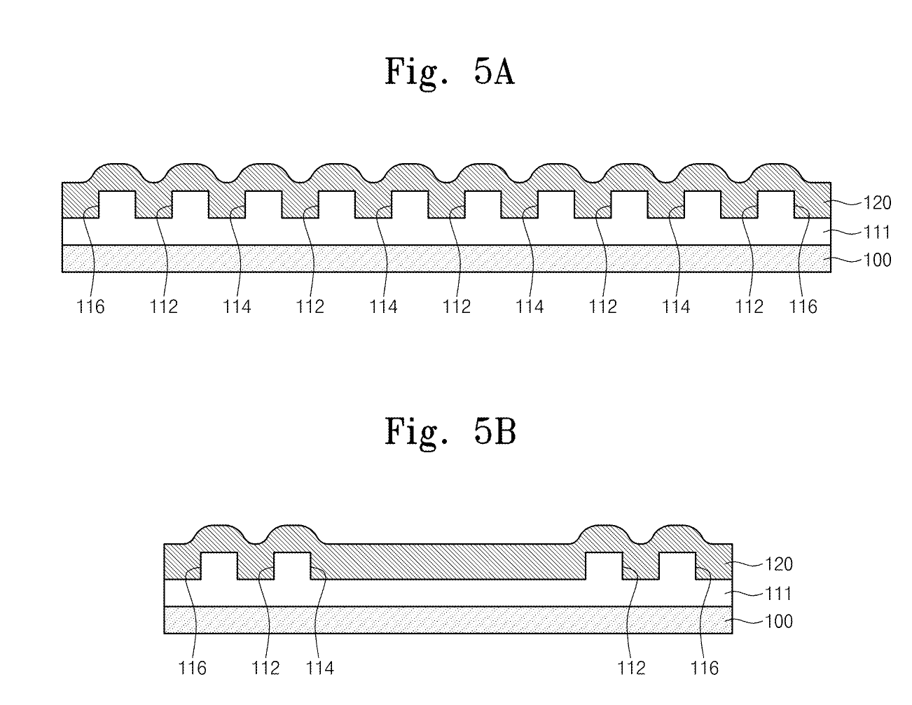

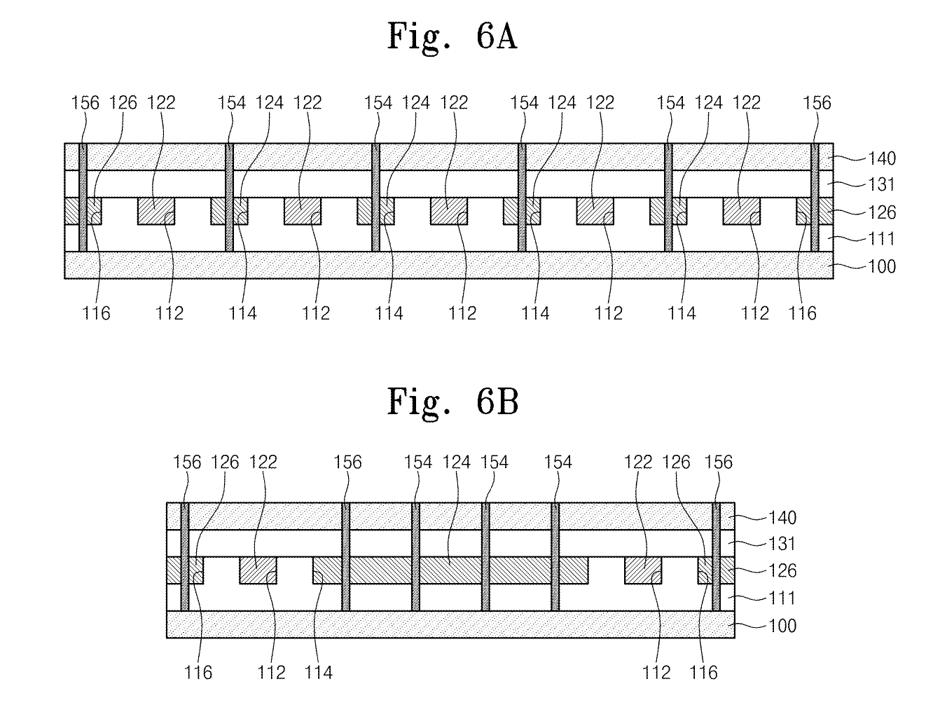

FIGS. 5A, 5B, 6A, and 6B are sectional views illustrating a process of manufacturing a capacitor according to another embodiment of the present invention. FIGS. 5A and 6A are sectional views taken along the line I-I′ of FIG. 1. FIGS. 5B and 6B are sectional views taken along the line II-II′ of FIG. 1.

Referring to FIGS. 5A and 5B, a first electrode layer 100 which is described with reference to FIGS. 3A and 3B is prepared. A first dielectric 111 may be formed on the first electrode layer 100. The first dielectric 111 may be an oxide layer.

First to third grooves 112, 114, and 116 may be formed in the first dielectric 111. In plan view, the first groove 112 may form a plurality of closed loops. In plan view, the second grooves 114 may be formed within the plurality of closed loops, respectively. The third grooves 116 may be formed outside the first groove 112 to surround the first groove 112. In plan view, each of the first to third grooves 112, 114, and 116 may have the same shape as that of each of the first to third conductive patterns 122, 124, and 126 which are described with reference to FIG. 1.

A conductive layer 120 may be formed on the first dielectric 111. The first to third grooves 112, 114, and 116 may be filled with the conductive layer 120. The conductive layer 120 may be formed of a metal. For example, the conductive layer 120 may be formed of one of copper, aluminum, and an alloy thereof.

Referring to FIGS. 6A and 6B, a planarization process may be performed using a top surface of the first dielectric 111 as an etch stop layer. Thus, the conductive layer 120 disposed outside the first to third grooves 112, 114, and 116 may be removed to respectively form first to third conductive patterns 122, 124, and 126 within the first to third grooves 112, 114, and 116. The first to third conductive patterns 122, 124, and 126 may be portions of the conductive layer 120 remaining within the first to third grooves 112, 114, and 116. The first to third conductive patterns 122, 124, and 126 may be the first to third conductive patterns 122, 124, and 126 which are described with reference to FIG. 1.

After the first to third conductive patterns 122, 124, and 126 are formed, a second dielectric 131 and a second electrode layer 140 may be successively formed on the first dielectric 111. The second dielectric 131 and the first dielectric 111 may be formed of the same material.

First contact plugs 154 passing through the second electrode layer 140, the second dielectric 130, the second conductive patterns 124, and the first dielectric 110 to contact the first electrode layer 100 and second contact plugs 156 passing through the second electrode layer 140, the second dielectric 131, the third conductive patterns 126, and the first dielectric 110 to contact the first electrode layer 100 may be formed.

According to the embodiments of the present invention, the first conductive pattern forming the closed loop in plan view is disposed between the first and second electrode layers, and the second conductive pattern electrically connected to the first and second electrode layers is disposed within the inner space surrounding by the closed loop. Thus, the effective overlapping area between the first conductive pattern and the second conductive pattern which generate the capacitance may be improved.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A capacitor comprising:
first and second electrode layers facing each other;
a first conductive pattern disposed between the first and second electrode layers, the first conductive pattern forming a closed loop in plan view;
a second conductive pattern disposed within an inner space surrounded by the closed loop of the first conductive pattern, the second conductive pattern being spaced from the first conductive pattern; and
a first contact plug passing through the second conductive pattern to contact the first and second electrode layers.

2. The capacitor of claim 1, wherein the first conductive pattern comprises first extension portions extending in a first direction parallel to a top surface of the first electrode layer and second extension portions extending in a second direction parallel to the top surface of the first electrode layer and crossing the first direction, and
wherein the first and second extension portions form a plurality of closed loops in plan view.

3. The capacitor of claim 2, wherein the plurality of closed loops define a plurality of inner spaces surrounded by the plurality of closed loops, respectively,
wherein the second conductive pattern is provided in plurality, and
wherein the plurality of second conductive patterns are disposed within the plurality of inner spaces, respectively.

4. The capacitor of claim 3, wherein the plurality of second conductive patterns extend in the first direction within the inner spaces.

5. The capacitor of claim 3, wherein the first extension portions and the second conductive patterns are alternately disposed in the second direction.

6. The capacitor of claim 3, wherein the plurality of second conductive patterns have the same length in the first direction.

7. The capacitor of claim 2, wherein one first extension portion of the first extension portions has a length greater than those of the other first extension portions.

8. The capacitor of claim 2, wherein the second extension portions are provided in pair, and
wherein one second extension portion of the pair of second extension portions connects one ends of the first extension portions to each other, and the other extension portion of the pair of second extension portions connects the other ends of the first extension portions to each other.

9. The capacitor of claim 1, further comprising a third conductive pattern between the first and second electrode layers,
wherein the third conductive pattern surrounds the outside of the first conductive pattern and is spaced from the first conductive pattern.

10. The capacitor of claim 9, wherein a capacitance per unit area between the first and second conductive patterns is equal to that per unit area between the first and third conductive patterns.

11. The capacitor of claim 9, wherein the first to third conductive patterns are disposed at the same level with respect to the top surface of the first electrode layer.

12. The capacitor of claim 11, further comprising:
a first dielectric disposed between the first to third conductive patterns and the first electrode layer; and
a second dielectric disposed between the first to third conductive patterns and the second electrode layer, the second dielectric filling spaces between the first to third conductive patterns,
wherein the first contact plug further passes through the first and second dielectrics.

13. The capacitor of claim 12, further comprising a second contact plug passing through the second dielectric, the third conductive pattern, and the first dielectric to contact the first and second electrode layers.

14. The capacitor of claim 9, wherein the first to third conductive patterns are manufactured through the same process.

15. The capacitor of claim 9, wherein the first conductive pattern comprises a first extension portion extending in the first direction parallel to the top surface of the first electrode layer and a second extension portion extending the second direction perpendicular to the first direction,
wherein the second conductive pattern extends in the first direction, and
wherein a distance between the first extension portion and the second conductive pattern in the second direction is equal to that between the second extension portion and the second conductive pattern in the first direction.

16. The capacitor of claim 15, wherein the third conductive pattern comprises a first portion extending in the first direction and a second portion extending in the second direction, and
wherein a distance between the first extension portion and the first portion in the second direction is equal to that between the second extension portion and the second portion in the first direction.

17. The capacitor of claim 16, wherein a distance between the first extension portion and the second conductive pattern in the second direction is equal to that between the first extension portion and the first portion in the second direction.

18. The capacitor of claim 1, wherein a distance between the first conductive pattern and the first electrode layer in a direction perpendicular to the top surface of the first electrode layer is equal to that between the first conductive pattern and the second electrode layer.
